(19) United States
(12) Patent Application Publication
(10) Pub. No.: US 2005/0280991 A1
(43) Pub. Date: Dec. 22, 2005

(54) Fast mountable screw assembly for CPU heat sink

(75) Inventor: C.H. Tsai, Hsing Chuang City (TW)

Correspondence Address: BACON & THOMAS, PLLC, 625 SLATERS LANE, FOURTH FLOOR, ALEXANDRIA, VA, 22314, US

(73) Assignee: HAMA NAKA SHOUKIN INDUSTRY CO., LTD., Hsing Chuang City (TW)

(21) Appl. No.: 10/872,484

(22) Filed: Jun. 22, 2004

(51) Int. Cl. H05K 7/20

(52) U.S. Cl. 361/697

(57) ABSTRACT

This invention relates to a fast mountable screw assembly for CPU heat sink, comprising a base unit, a fan unit and a heat fin unit. There are hollow bolt holes on four corners of the base unit and each bolt hole is filled with a fastener for a screw to pass through and being locked on the base unit plate. The base unit links to the heat fan unit at one side and the heat fin unit at other side, and a wind conduit is connected between the base unit and the heat fin unit. The specific design is the fastener which has a spring, and the center hole of the fastener will accept the screw. The bottom of the fastener will be punched with a special tool to be pivoted on the base unit, so the fastener is moveable but never falling off. In practice, this heat sink is easy, fast and convenient to assemble with components interchangeable to gain the greatest economical benefit.

### FIELD OF THE INVENTION

This invention concerns a fast mountable screw assembly for CPU heat sink with emphasis on easy, fast and convenient to assemble.

### BACKGROUND OF THE INVENTION

The early heat sink used in the computer was simply a heat fin unit or the heat paste to achieve the heat dissipation. Due to the poor performance, there came the fan unit structure. Up to now, the combination of fan unit and heat fin unit is a main stream. As shown in FIGS. 1 and 2, this heat sink (5) is locked by the screw (50) attached with a spring (51) and locked with a circlip (52) to prevent it from falling off.

This heat sink offers better performance, but this way of screw locking is only applicable to a specified panel. When it is necessary to change the panel, the complete set of the screw, the spring and the circlip has to be dismounted and a complete new set of the screw, the spring and the circlip has to be mounted to the panel. It seems such a change is troublesome. In the meantime, such a screw along with a spring and a circlip has to be re-fabricated. Such doing is apparently costly, no economical gain. It is learned that the existing heat sink is not a sound design yet.

Because the prior art of the heat sink has much trouble to assemble and lacks of interchangeability, the inventor has worked hard for year to improving and eventually come up with this invention.

### SUMMARY OF THE INVENTION

The main object of this invention is to provide a novel fast mountable screw assembly for CPU heat sink for easy and fast assembly and for the high interchangeability, universally applicable to every model of computer.

To achieve the above mentioned object, the CPU heat sink designed by this invention structurally mainly comprises a base unit, a fan unit and a heat fin unit. There are four bolt holes on each corner and each bolt hole is filled with a fastener for accepting the screw to be locked on the panel. The base unit has the fan unit on one side and the heat fin unit on the other side. There are wind conduits to connect the heat fin unit to the base unit. In particular, the fastener is attached a spring on its periphery and has a go through hole in the center for the screw to pass through. The bottom of the fastener is punched to be riveted on the base unit plate ensuring that each fastener is firmly locked in the bolt hole, even moveable, but never falling off. Such a structure of the heat sink simplifies the operation and the only choice is to select an adequate screw. It is an easy, simple, time-saving and money-saving assembly.

The features and merits of this invention will be explained in great detail with the aid of the preferable embodiments illustrated in the drawings attached.

### BRIEF DESCRIPTION OF THE DRAWINGS

FIG. 1 shows the cross section of the fastening system of the prior art of the heat sink.

FIG. 2 shows the cross section of other fastening system of the prior art of the heat sink.

FIG. 3 shows the structural appearance of the heat sink of this invention.

FIG. 4 shows the partial cross section of the fastening system of this invention (1).

FIG. 5 shows the partial cross section of another fastening system of this invention (2).

FIG. 6 shows the cross section of the fastening system of this invention.

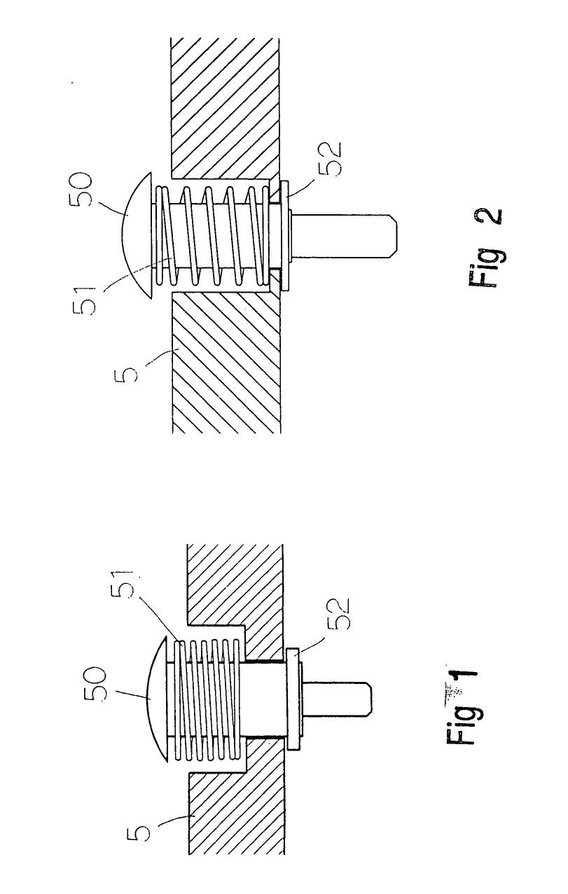

### DETAILED DESCRIPTION OF THE INVENTION

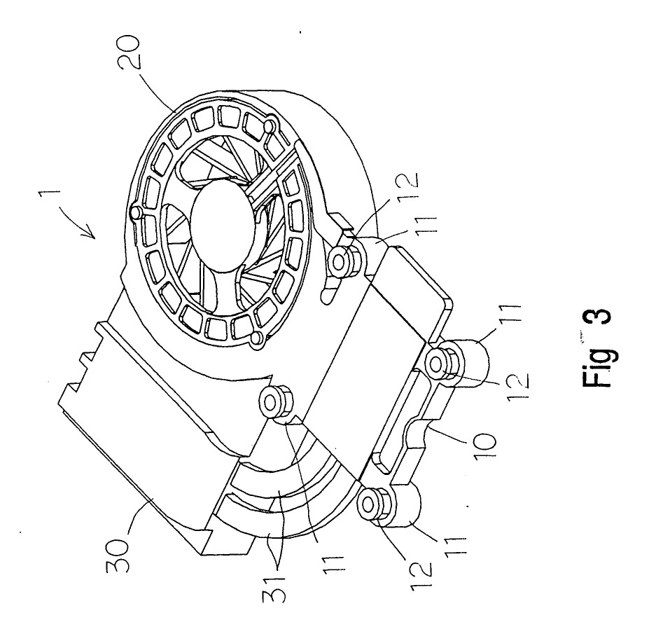

This invention relates to a fast mountable screw assembly for the CPU heat sink as shown in FIG. 3. The heat sink (1) mainly consists of a base unit (10), a fan unit (20) and a fin unit (30) in which The base unit (10) has the bolt hole (11) on the four corners and each bolt hole (11) is filled with a fastener (12) which is locked on the panel by a screw (123).

The base unit (10) is connected to the fan unit (20) at one side and to the fin unit (30) at other side. The cooling air generated in the fan unit (20) will flow to the fin unit (30) and the base unit (10) through the air conduit (31).

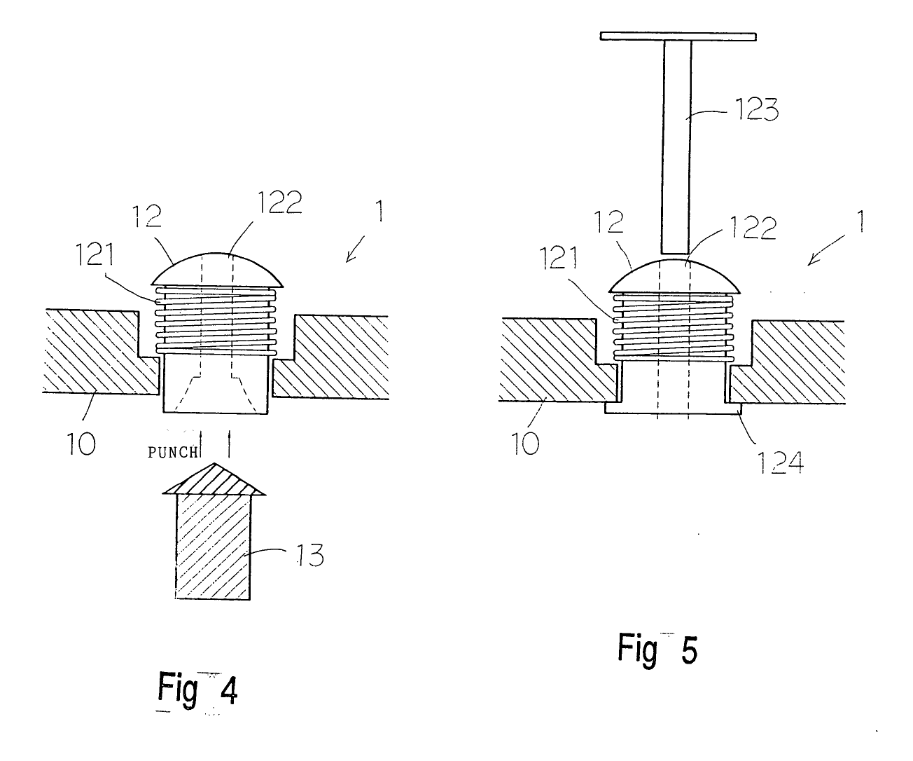

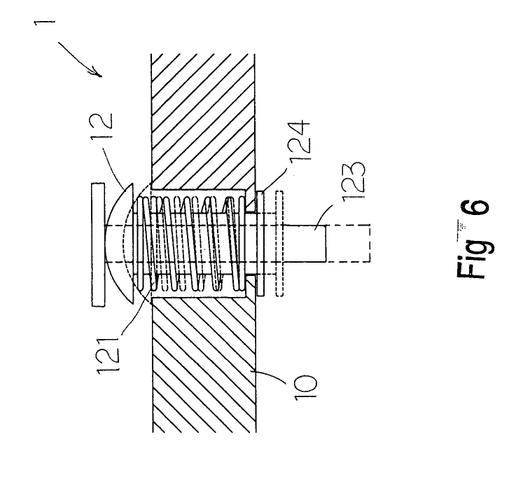

As shown in FIGS. 4 through 6, the major characteristics of this invention is that the fastener (12) is peripherally attached with the spring (121) with a center hole (122) to accept the screw (123) for locking up the fastener (12). The bottom of the fastener (12) is punched with a specific puncher (13) riveted on the retaining seat (11). The fastener (12) is moveable, but never falls off.

The heat sink (1) is designed to mount on the panel by the base unit (10) with each fastener (12) a four corners and the screw (123) will pass the center hole (122) to lock up the heat sink (1) on the panel. In case it is necessary to relocate this heat sink (1) to other panel, the action is very simple, take off the old screw (123) and use the new screw (123) to mount the heat sink (1) to other panel. Really it is easy, relaxed and time-effective work.

Viewing from he above statement, it is learned that the specific design of screw, the base unit and the top cap for the heat sink renders easy, fast assembly and the good performance is therefore assured. This is a novel design enough justified for a grant of patent.

1. A fast mountable screw assembly for CPU heat sink mainly comprises a base unit, a fan unit and a heat fin unit,
the base unit provides four bolt holes at each corner to hold a fastener with a center hole through which a screw will pass and lock the heat sink on the panel, the base unit is connected to the fan unit on one side and the heat fin unit on other side, an air conduit is linked between the heat fin unit and the base unit,
the fastener is encircled with a spring, the center hole of the fastener will accept the screw, the bottom of the fastener is punched with a specified puncher to rivet the bottom of the fastener on the base unit plate, in this manner, the fastener is moveable, but never falls off,
this fast mountable screw assembly renders easy assembly of the heat sink to the panel and intensifies the high interchangeability of parts universally applicable to every model of CPU with great economical benefit.
